(19) United States
(12) Patent Application Publication
(10) Pub. No.: US 2012/0169430 A1
(43) Pub. Date: Jul. 5, 2012

(54) INPUT APPARATUS ON CHIP FOR DIFFERENTIAL SIGNALS AND BALUN THEREOF

(75) Inventors: Shih-Ming Wang, Hsinchu City (TW); Ming-Wei Lee, Taichung City (TW)

(73) Assignee: INDUSTRIAL TECHNOLOGY RESEARCH INSTITUTE, Hsinchu (TW)

(21) Appl. No.: 13/072,782

(22) Filed: Mar. 28, 2011

(30) Foreign Application Priority Data
Dec. 31, 2010 (TW) 99147308

(51) Int. Cl. H03H 5/10

(52) U.S. Cl. 333/26

(57) ABSTRACT

An on-chip balun is disclosed. The balun includes a first transmission line, a second transmission line and a coupling transmission line. A terminal of the first transmission line receives a first signal. A terminal of the second transmission line receives a second signal and the other terminal of the second transmission line is coupled to a reference voltage. A terminal of the coupling transmission line receives the reference voltage, and the other terminal is directly connected to the other terminal of the first transmission line. The coupling transmission line and the second transmission line are disposed in parallel for coupling the second signal to generate a coupling signal on the coupling transmission line. The first and second signals are differential signals and the phases of the second signal and the coupling signal are opposite.

### CROSS-REFERENCE TO RELATED APPLICATION

This application claims the priority benefit of Taiwan application serial no. 99147308, filed Dec. 31, 2010. The entirety of the above-mentioned patent application is hereby incorporated by reference herein and made a part of this specification.

### TECHNICAL FIELD

The disclosure relates to a balun structure, and more particularly to an on-chip balun structure.

### BACKGROUND

A balun is typically disposed on a chip to receive differential signals. Referring to FIG. 1, a schematic diagram of a conventional input apparatus 100 for differential signals is shown. The input apparatus 100 for differential signals include a differential amplifier 130 and two baluns 110 and 120. The balun 120 is a transformer formed by coils to receive a differential signal VIN. Moreover, the balun 120 is coupled to the differential amplifier 130 and transmits signals to the balun 110 through the differential amplifier 130. The balun 110 is likewise formed by coils, and the balun 110 is used to generate an output signal Vout at one terminal. However, since the baluns 110 and 120 are formed by coils, the area occupied by the baluns 110 and 120 is huge. Additionally, due to an insufficient coupling rate, signal losses result when signal coupling occurs between the coils.

FIG. 2 is a schematic diagram of a conventional balun 200. The balun 200 is also formed by coils, and signal transmission and reception is performed through points P, PB, S, and SB. The size of the conventional balun 200 is inversely proportional to the frequency of the signal transmission thereof. Under a 6 GHz transmission frequency, the required length of the balun 200 is very long, and the impedance produced by the overlong coils also generates a large loss. Moreover, since the balun 200 not constructed from magnetic materials during on-chip manufacturing, the magnetic coupling rate of the balun 200 is insufficient.

### SUMMARY

An on-chip balun effectively combining received differential signals and generating single-end output signals is introduced herein.

An input apparatus for differential signals effectively combining received differential signals and generating single-end output signals is introduced herein.

According to an exemplary embodiment, an on-chip balun includes a first transmission line, a second transmission line, and a coupling transmission line. The first transmission line has a terminal receiving a first signal, the second transmission line has a terminal receiving a second signal, and the other terminals thereof are coupled to a reference voltage. The coupling transmission line has a terminal receiving the reference voltage and another terminal directly connected to the other terminal of the first transmission line. The coupling transmission line and the second transmission line are disposed in parallel for coupling the second signal to generate a coupling signal on the coupling transmission line. Moreover, the first signal and the second signal are differential signals, and the phases of the second signal and the coupling signal are opposite.

According to an exemplary embodiment, an input apparatus for differential signals is disposed on a chip and adapted for receiving a plurality of differential signals. The input apparatus for differential signals includes a plurality of baluns, in which each of the baluns includes a first transmission line, a second transmission line, and a coupling transmission line. The first transmission line has a terminal receiving a first signal, the second transmission line has a terminal receiving a second signal, and the other terminals thereof are coupled to a reference voltage. The coupling transmission line has a terminal receiving the reference voltage and another terminal directly connected to the other terminal of the first transmission line. The coupling transmission line and the second transmission line are disposed in parallel for coupling the second signal to generate a coupling signal on the coupling transmission line. Moreover, the first signal and the second signal are differential signals, and the phases of the second signal and the coupling signal are opposite.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a schematic diagram of a conventional input apparatus for differential signals.

FIG. 2 is a schematic diagram of a conventional balun.

FIG. 3 is a schematic diagram of an on-chip balun according to an exemplary embodiment.

FIG. 4 is a schematic diagram of an on-chip balun according to an exemplary embodiment.

FIG. 5A is a schematic diagram of an on-chip balun according to an exemplary embodiment.

FIG. 5B is a schematic diagram of the on-chip balun depicted in FIG. 5A according to an exemplary embodiment.

FIG. 6 is a schematic diagram of an input apparatus for differential signals according to an exemplary embodiment.

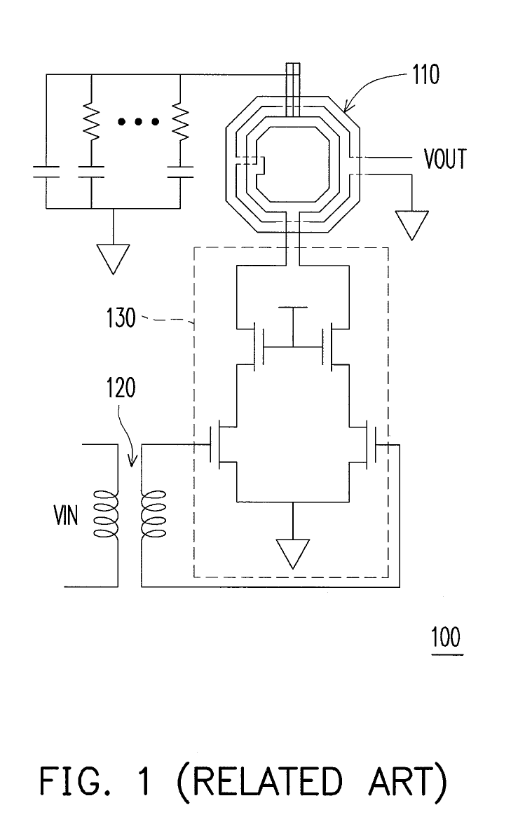

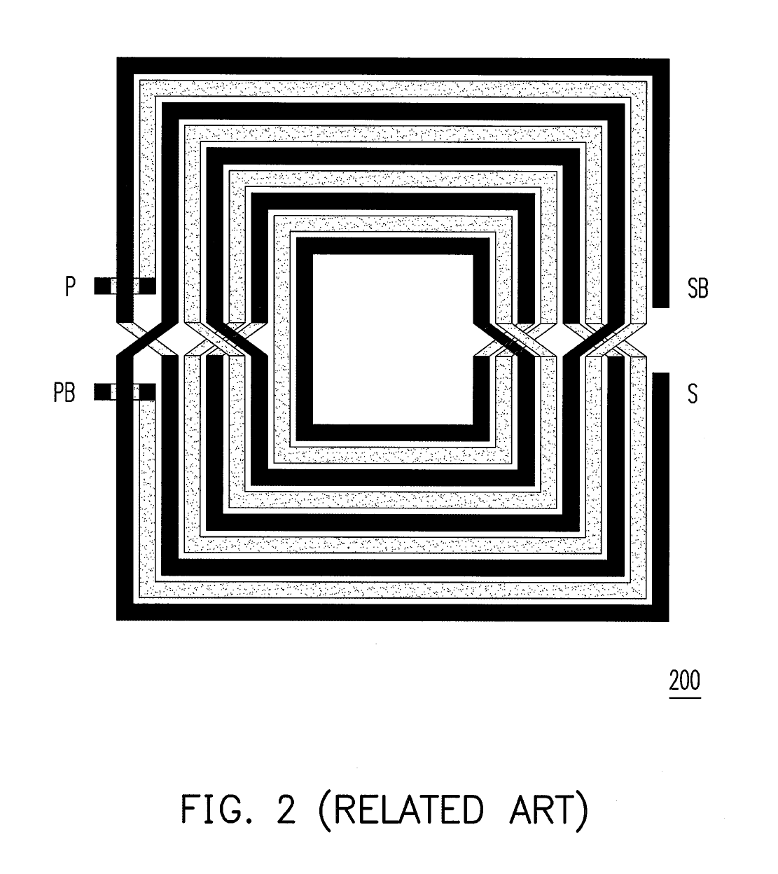

### DESCRIPTION OF EMBODIMENTS

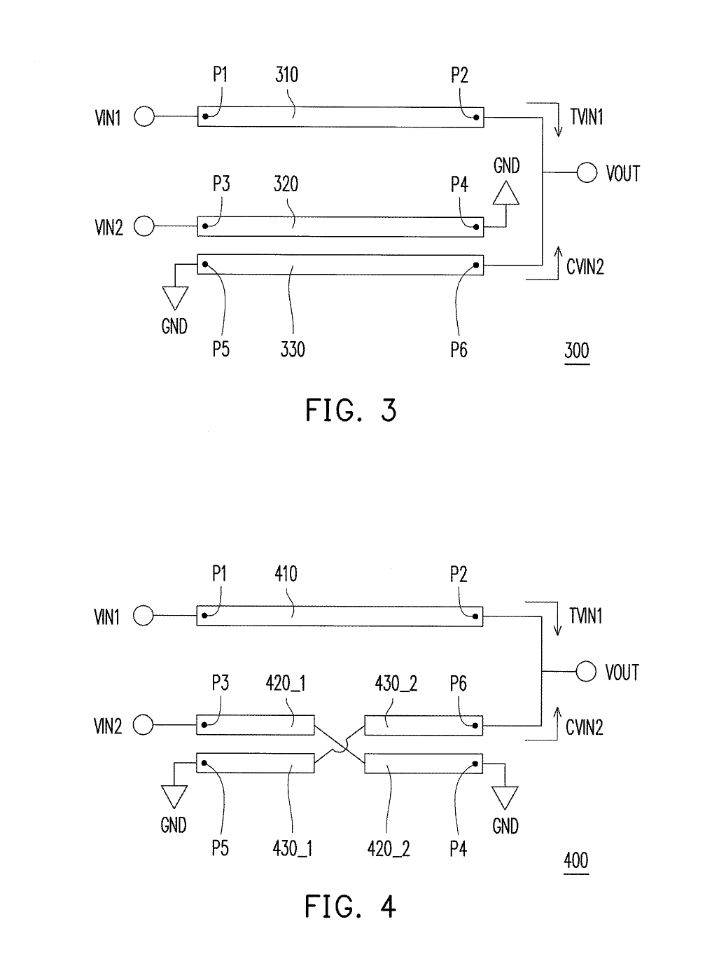

Referring to FIG. 3, a schematic diagram of an on-chip balun 300 according to an exemplary embodiment is shown. The on-chip balun 300 includes a transmission line 310, a transmission line 320, and a coupling transmission line 330. The transmission line 310 has a terminal P1 receiving a signal VIN1, and a signal TVIN1 is transmitted through another terminal P2 of the transmission line 310. The transmission line 320 has a terminal P3 receiving a signal VIN2 and another terminal P4 coupled to a reference voltage GND. The coupling transmission line 330 has a terminal P5 receiving the reference voltage GND and another terminal P6 directly connected to the other terminal P2 of the transmission line 310. The coupling transmission line 330 and the transmission line 320 are disposed in parallel for coupling the signal VIN2 to generate a coupling signal CVIN2 on the coupling transmission line 330. The signal VIN1 and the signal VIN2 are differential signals, and the phases of the signal VIN2 and the coupling signal CVIN2 are opposite.

Accordingly, terminal P6 of the coupling transmission line 330 is directly connected to the other terminal P2 of the transmission line 310. Therefore, the coupling signal CVIN2 and the transmission signal TVIN1 may be directly added on a common connection point between the terminal P6 of the coupling transmission line 330 and the terminal P2 of the transmission line 310, and thereby obtaining an output signal Vout having twice the voltage as the transmission signal TVIN1.

A practical operation based on the on-chip balun 300 is described below as an illustrative example. When the transmission line 310 receives a positive signal VIN1 through the terminal P1, the positive signal VIN1 is transmitted to the terminal P2 and becomes the transmission signal TVIN1. Conversely, the transmission line 320 receives a negative signal VIN2 through the terminal P3, and the terminal P4 of the transmission line 320 is coupled to the ground voltage (i.e. 0 V) serving as the reference voltage GND. The coupling transmission line 330 is coupled to the negative signal VIN2 received by the transmission line 320 to generate the coupling signal CVIN2 on the coupling transmission line 330 having an opposite phase (i.e. positive) relative to the phase of the signal VIN2. A polarity inversion function is achieved by the coupling of the coupling transmission line 330 and the transmission line 320 and due to the reverse current flow induced in the coupling transmission line 330. Accordingly, the coupling signal CVIN2 and the transmission signal TVIN1 are added to each other on the common connection point between the coupling transmission line 320 and the transmission line 310, and thereby the output signal Vout which is twice the signal TVIN1 is generated.

It should be noted that, the transmission lines 310 and 320 and the coupling transmission line 330 may all be formed by a material (e.g. a metallic layer) used in a chip manufacturing process to construct transmission lines.

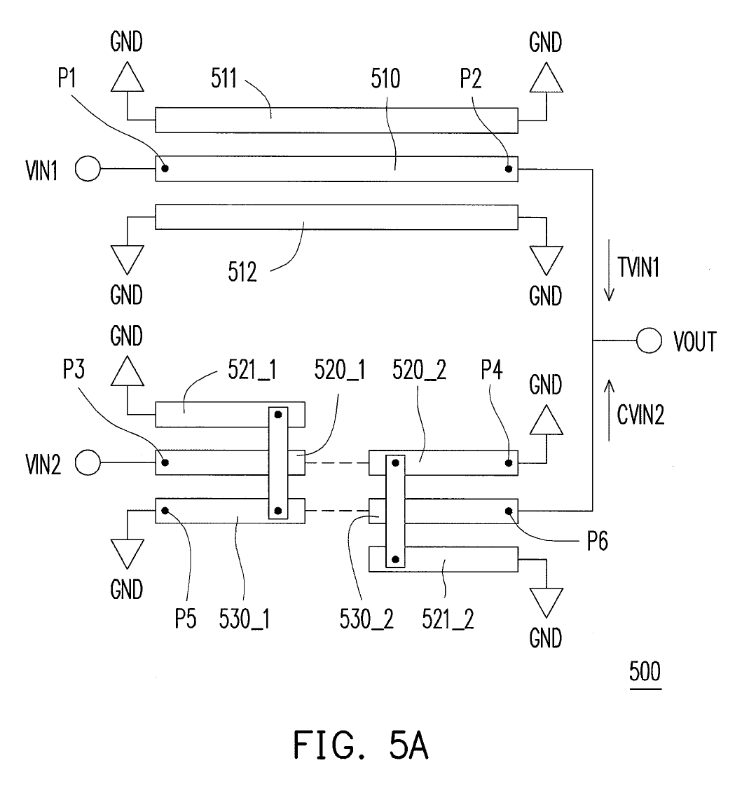

Referring to FIG. 4, a schematic diagram of an on-chip balun 400 according to an exemplary embodiment is shown. The balun 400 includes a transmission line 410, a coupling transmission line formed by the coupling transmission sections 430_1 and 430_2, and a transmission line formed by the transmission sections 420_1 and 420_2. The transmission line 410 has a terminal P1 receiving a signal VIN1, and a signal TVIN1 is transmitted through another terminal P2 of the transmission line 410. The transmission section 420_1 has a terminal P3 receiving a signal VIN2, and the transmission section 420_2 has another terminal P4 coupled to a reference voltage GND. The transmission sections 420_1 and 420_2 may be connected to each other through a metallic line, for example. The coupling transmission section 430_1 has a terminal P5 coupled to the reference voltage GND, and the coupling transmission section 430_2 may be connected to the coupling transmission section 430_1 through a metallic line, for example. The coupling transmission section 430_1 is coupled to the signal VIN2 received by the transmission section 420_1 to transmit a coupling signal CVIN2 through the terminal P6 of the transmission section 430_2 having the opposite phase as the signal VIN2. The coupling signal CVIN2 and the transmission signal TVIN1 are added to each other on a common connection point between the coupling transmission section 430_2 and the transmission line 410, and thereby the output signal Vout which is twice the signal TVIN1 is generated.

The coupling section 430_1 and the transmission section 420_1 are disposed in parallel for coupling the signal VIN2 to generate a coupling signal on the coupling transmission section 430_1. Moreover, the coupling section 430_2 and the transmission section 420_2 are disposed in parallel to transmit the coupling signal CVIN2 on the coupling transmission section 430_2.

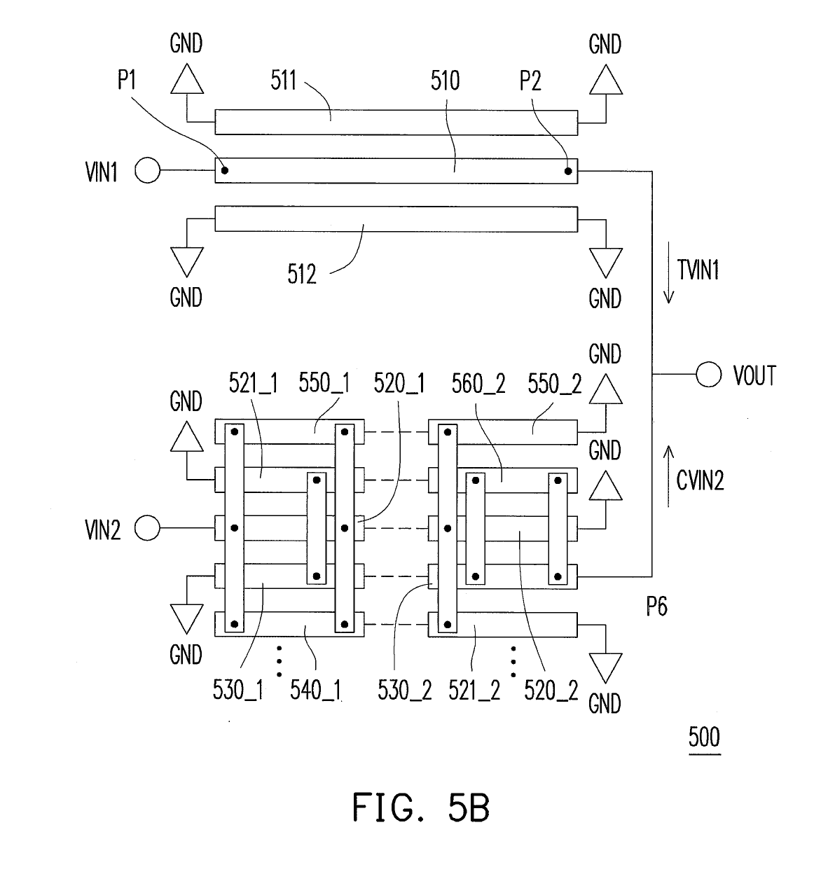

Referring to FIG. 5A, a schematic diagram of an on-chip balun 500 according to an exemplary embodiment is shown. The on-chip balun 500 includes a transmission line 510, the isolating transmission lines 511 and 512, the transmission sections 520_1 and 520_2, an isolating transmission section 521_2, the coupling transmission sections 530_1 and 530_2, and an isolating coupling transmission section 521_1. The transmission line 510 has a terminal P1 receiving a signal VIN1. The transmission section 520_1 has a terminal P3 receiving a signal VIN2 reversed from the signal VIN1. The transmission section 520_2 has a terminal P4 coupled to the reference voltage GND. The coupling transmission section 530_1 has a terminal P5 coupled to the reference voltage GND, and the coupling transmission section 530_2 has a terminal P6 transmitting a coupling signal CVIN2 generated on the transmission sections 530_1 and 530_2 according to the received signal VIN2.

The isolating transmission lines 511 and 512 are disposed in parallel at two sides of the transmission line 510, and the isolating transmission lines 511 and 512 are coupled to the reference voltage (i.e. the ground voltage). The isolating coupling transmission section 521_1 is disposed at a first side of the transmission section 520_1, and the isolating coupling transmission section 521_2 is disposed at a second side of the coupling transmission section 530_2. The first side and the second side are on different sides with respect to the coupling transmission section 530_1 and the coupling transmission section 530_2. Moreover, one terminal of the isolating coupling transmission section 521_1 and the coupling transmission section 530_1 is coupled to the ground voltage GND, and the terminals of the isolating coupling transmission section 521_1 and the coupling transmission section 530_1 which are not coupled to the ground voltage GND are coupled to each other. Similarly, one terminal of the transmission section 520_2 and the isolating coupling transmission section 521_2 is coupled to the ground voltage GND, and the terminals of the transmission section 520_2 and the isolating coupling transmission section 521_2 which are not coupled to the ground voltage GND are coupled to each other.

Referring to FIG. 5B, a schematic diagram of the on-chip balun 500 depicted in FIG. 5A according to an exemplary embodiment is shown. In the balun 500 as shown in FIG. 5B, one or a plurality of the expanded isolating transmission sections 540_1 may be disposed at a side of the coupling transmission section 530_1 not adjacent to the transmission section 520_1. Moreover, one or a plurality (e.g., N or M, where N and M are positive integers) of the expanded isolating coupling transmission section 550_1 may be disposed at a side of the isolating coupling transmission section 521_1 not adjacent to the transmission section 520_1 (i.e., one side of the transmission section 520_1). The two terminals of the expanded isolating transmission section 550_1, the transmission section 520_1, and the expanded isolating transmission section 540_1 are coupled to each other.

In addition, one or a plurality of the expanded isolating coupling transmission sections (not drawn) may be disposed at a side of the coupling transmission section 530_1 not adjacent to the transmission section 520_1 (i.e., one side of the transmission section 520_1). These expanded isolating coupling transmission sections and the expanded isolating transmission sections 540_1 are alternately disposed at the side of the coupling transmission section 530_1 not adjacent to the transmission section 520_1. One terminal of these expanded isolating coupling transmission sections is coupled to the ground voltage GND, and the other terminals of the expanded isolating coupling transmission sections are coupled to the terminals of the coupling transmission section 530_1 and the isolating coupling transmission section 521_1 which are not coupled to the ground voltage GND.

Furthermore, one or a plurality of expanded isolating coupling transmission sections (not drawn) may be disposed at a side of the isolating coupling transmission section 521_1 not adjacent to the transmission section 520_1. These expanded isolation coupling transmission sections and the expanded isolation coupling transmission section 550_1 are alternately disposed at the side of the coupling transmission section 521_1 not adjacent to the transmission section 520_1. One terminal of these expanded isolating coupling transmission sections is coupled to the ground voltage GND, and the other terminals of the expanded isolating coupling transmission sections are coupled to the terminals of the coupling transmission section 530_1 and the isolating coupling transmission section 521_1 which are not coupled to the ground voltage GND.

As a matter of course, the expanded isolating coupling transmission section 560_2 and the expanded coupling transmission section 550_2 are disposed in sequence at the side of the transmission section 520_2 not adjacent to the coupling transmission section 530_2. Moreover, the expanded coupling transmission section 550_2 has a terminal coupled to the ground voltage GND. Additionally, the terminal of the expanded coupling transmission section 550_2 not coupled to the ground voltage GND is coupled to the terminals of the isolation transmission section 521_2 and the transmission section 520_2 which are not coupled to the ground voltage GND. The two terminals of the expanded isolating coupling section 560_2 are coupled to the two terminals of the coupling transmission section 530_2. Furthermore, one or a plurality of sets of the expanded isolating coupling transmission sections and the expanded isolating transmission sections, such as the expanded isolating coupling transmission section 560_2 and the expanded isolating transmission section 550_2 may be alternately disposed at the side of the transmission section 520_2 not adjacent to the coupling transmission section 530_2. Moreover, by alternately coupling a plurality of transmission lines, the amount of signal coupling can be effectively increased.

Naturally, the afore-described expanded isolating coupling transmission section 560_2 and the expanded isolating transmission section 550_2 may also be disposed at the side of the isolating transmission section 521_2 not adjacent to the coupling transmission section 530_2 (i.e., one side of the transmission section 520_2) as an expanded. Further, by alternately coupling a plurality of transmission lines, the amount of signal coupling can be effectively enhanced.

In the exemplary embodiment shown in FIG. 5B, the expanded isolating coupling transmission section 560_2 is not directly adjacent to each of the transmission sections 520_1 and 520_2. Moreover, each of the expanded isolating coupling transmission sections 550_2 and 550_1 is not directly adjacent to each of the coupling transmission sections 530_1 and 530_2.

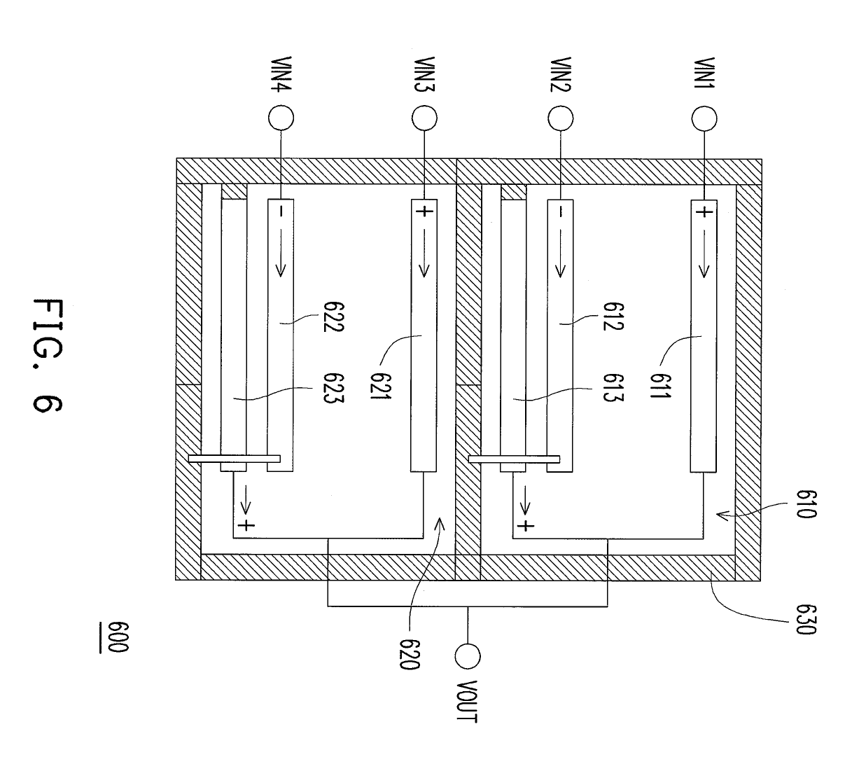

Referring to FIG. 6, a schematic diagram of an input apparatus 600 for differential signals according to an exemplary embodiment is shown. The input apparatus 600 for differential signals includes a plurality of baluns 610 and 620. The balun 610 includes the transmission lines 611 and 612 and a coupling transmission line 613. The balun 620 includes the transmission lines 621 and 622 and a coupling transmission line 623. It should be emphasized that the baluns 610 and 620 in the exemplary embodiment are the same as the balun 300 in the first embodiment of the disclosure. It should also be noted that the coupling transmission lines 613 and 623 are coupled to the reference voltage through a ground ring 630.

A directly connected terminal of the transmission line 611 and the coupling transmission line 613 in the balun 610 is coupled to a directly connected terminal of the transmission line 621 and the coupling transmission line 623 in the balun 620, for forming an output terminal of the input apparatus 600 for differential signals to generate an output signal Vout. In the present embodiment, since two stages of the baluns 610 and 620 are parallel connected, the output signal Vout is four times the signal VIN1 (i.e., when the signals VIN1 and VIN2 are equal in magnitude, the signals VIN1 and VIN2 are differential signals, and the signals VIN3 and VIN4 are differential signals).

In view of the foregoing, an output signal from a single-end terminal is generated by using parallel-coupled transmission lines and coupling transmission lines for coupling and reversing one of the differential signals, and adding the other one of the differential signals with the reversed different signal. Accordingly, the disclosed balun needs only transmission lines to construct, without the need for extremely long transmission lines and a large layout area. Moreover, by adopting a directly connected signal addition operation, the loss resulting from an insufficient coupling rate can be prevented. In addition, with transmission lines being used as the essential components, the issue of electromagnetic flux leakage is mitigated.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An on-chip balun, comprising:
a first transmission line having a terminal for receiving a first signal;
a second transmission line having a terminal for receiving a second signal and another terminal coupled to a reference voltage; and
a coupling transmission line having a terminal for receiving the reference voltage and another terminal directly connected to the other terminal of the first transmission line, the coupling transmission line and the second transmission line are disposed in parallel for coupling the second signal to generate a coupling signal on the coupling transmission line,
wherein the first signal and the second signal are differential signals, and the phases of the second signal and the coupling signal are opposite.

2. The on-chip balun as claimed in claim 1, the second transmission line comprising a first transmission section and a second transmission section, the coupling transmission line comprising a first coupling transmission section and a second coupling transmission section, wherein the first transmission section and the first coupling transmission section are disposed in parallel, and the second transmission section and the second coupling transmission section are disposed in parallel.

3. The on-chip balun as claimed in claim 2, wherein the first coupling transmission section is disposed at a first side of the first transmission section, the second coupling transmission section is disposed at a second side of the second transmission section, and the first side and the second side are opposite.

4. The on-chip balun as claimed in claim 2, further comprising:
an isolating coupling transmission section disposed at the side of the first transmission section not adjacent to the first coupling transmission section and the isolating coupling transmission section disposed in parallel with the first transmission section, the first isolating coupling transmission section having a terminal coupled to the reference voltage; and
an isolating transmission section disposed at the side of the second coupling transmission section not adjacent to the second transmission section and disposed in parallel with the second coupling transmission section, the second isolating transmission section having a terminal coupled to the reference voltage,
wherein the terminal of the isolating coupling transmission section not connected to the reference voltage is coupled to the terminal of the first coupling transmission section not connected to the reference voltage, and the terminal of the isolating transmission section not connected to the reference voltage is coupled to the terminal of the second transmission section not connected to the reference voltage.

5. The on-chip balun as claimed in claim 4, further comprising:
a first isolating transmission line disposed at a side of the first transmission line and disposed in parallel with the first transmission line, the first isolating transmission line being coupled to the reference voltage; and
a second isolating transmission line disposed at another side of the first transmission line and disposed in parallel with the first transmission line, the second isolating transmission line being coupled to the reference voltage.

6. The on-chip balun as claimed in claim 2, further comprising:
N first expanded isolating coupling transmission sections, wherein N is a positive integer;
N first expanded isolating transmission sections, each of the first expanded isolating transmission sections and each of the first expanded isolating coupling transmission sections alternately disposed at one side or two sides of the first transmission section, wherein each of the first expanded isolating coupling transmission sections is not directly adjacent to the first transmission section, and each of the first expanded isolating transmission sections is not directly adjacent to the first coupling transmission section;
M second expanded isolating coupling transmission sections, wherein M is a positive integer; and
M second expanded isolating transmission sections, each of the second expanded isolating transmission sections and each of the second expanded isolating coupling transmission sections alternately disposed at one side or two sides of the second transmission section, wherein each of the second expanded isolating coupling transmission sections is not directly adjacent to the second transmission section, and each of the second expanded isolating transmission sections is not directly adjacent to the second coupling transmission section.

7. An input apparatus for differential signals disposed on a chip, adapted for receiving a plurality of differential signals, comprising:
a plurality of baluns, each of the baluns comprising:
a first transmission line having a terminal receiving a first signal;
a second transmission line having a terminal receiving a second signal and another terminal coupled to a reference voltage; and
a coupling transmission line having a terminal receiving the reference voltage and another terminal directly connected to the other terminal of the first transmission line, the coupling transmission line and the second transmission line are disposed in parallel for coupling the second signal to generate a coupling signal on the coupling transmission line,
wherein the first signal and the second signal are differential signals, and the phases of the second signal and the coupling signal are opposite.

8. The input apparatus for differential signals as claimed in claim 7, wherein the terminal coupling the first transmission line and the coupling transmission line in each of the baluns is a single-end signal generating terminal, and each of single-end signal generating terminals in each of the baluns is coupled to each other to form an output terminal of the input apparatus for differential signals.

9. The input apparatus for differential signals as claimed in claim 7, wherein the second transmission line in each of the baluns comprises a first transmission section and a second transmission section, the coupling transmission line comprises a first coupling transmission section and a second coupling transmission section, the first transmission section and the first coupling transmission section are disposed in parallel, and the second transmission section and the second coupling transmission section are disposed in parallel.

10. The input apparatus for differential signals as claimed in claim 9, wherein the first coupling transmission section in each of the baluns is disposed at a first side of the first transmission section, the second coupling transmission section is disposed at a second side of the second transmission section, and the first side and the second side are opposite.

11. The input apparatus for differential signals as claimed in claim 9, wherein each of the baluns further comprises:
an isolating coupling transmission section disposed at the side of the first transmission section not adjacent to the first coupling transmission section and disposed in parallel with the first transmission section, the first isolating coupling transmission section having a terminal coupled to the reference voltage; and
an isolating transmission section disposed at the side of the second coupling transmission section not adjacent to the second transmission section and disposed in parallel with the second coupling transmission section, the second isolating transmission section having a terminal coupled to the reference voltage, wherein the terminal of the isolating coupling transmission section not connected to the reference voltage is coupled to the terminal of the first coupling transmission section not connected to the reference voltage, and the terminal of the isolating transmission section not connected to the reference voltage is coupled to the terminal of the second transmission section not connected to the reference voltage.

12. The input apparatus for differential signals as claimed in claim 11, wherein each of the baluns further comprises:
a first isolating transmission line disposed at a side of the first transmission line and disposed in parallel with the first transmission line, the first isolating transmission line being coupled to the reference voltage; and
a second isolating transmission line disposed at another side of the first transmission line and disposed in parallel with the first transmission line, the second isolating transmission line being coupled to the reference voltage.

13. The input apparatus for differential signals as claimed in claim 8, wherein each of the baluns further comprises:
N first expanded isolating coupling transmission sections, wherein N is a positive integer; N first expanded isolating transmission sections, each of the first expanded isolating transmission sections and each of the first expanded isolating coupling transmission sections alternately disposed at one side or two sides of the first transmission section, wherein each of the first expanded isolating coupling transmission sections is not directly adjacent to the first transmission section, and each of the first expanded isolating transmission sections is not directly adjacent to the first coupling transmission section;
M second expanded isolating coupling transmission sections, wherein M is a positive integer; and
M second expanded isolating transmission sections, each of the second expanded isolating transmission sections and each of the second expanded isolating coupling transmission sections alternately disposed at one side or two sides of the second transmission section, wherein each of the second expanded isolating coupling transmission sections is not directly adjacent to the second transmission section, and each of the second expanded isolating transmission sections is not directly adjacent to the second coupling transmission section.
